(19) United States
(12) Patent Application Publication
(10) Pub. No.: US 2015/0115949 A1
(43) Pub. Date: Apr. 30, 2015

(54) BRIDGE CIRCUIT AND MAGNETIC SENSOR INCLUDING THE CIRCUIT

(71) Applicant: MURATA MANUFACTURING CO., LTD., Nagaokakyo-Shi (JP)

(72) Inventor: ATSUSHI ITAGAKI, Nagaokakyo-shi (JP)

(21) Appl. No.: 14/527,846

(22) Filed: Oct. 30, 2014

Related U.S. Application Data
(63) Continuation of application No. PCT/JP2013/002703, filed on Apr. 22, 2013.

(30) Foreign Application Priority Data
May 16, 2012 (JP) 2012-112497

(51) Int. Cl. G01R 33/09

(52) U.S. Cl. CPC G01R 33/09
USPC 324/247

(57) ABSTRACT

A magnetic sensor having a large magnetic-field detection angle range and a bridge circuit used in the magnetic sensor, in each of multiple MR elements in the bridge circuit, multiple strips, on the whole, along a direction substantially orthogonal to a magnetic-field detection direction are arranged in parallel at certain intervals and are sequentially connected so as to be folded back and, in each of the multiple strips, multiple strips along the magnetic-field detection direction are arranged in parallel at certain intervals and are sequentially connected so as to be folded back to form a zigzag pattern in which the multiple strips are electrically connected in series to each other.

### CROSS REFERENCE TO RELATED APPLICATIONS

The present application is a continuation of PCT/JP2013/002703 filed Apr. 22, 2013, which claims priority to Japanese Patent Application No. 2012-112497, filed May 16, 2012, the entire contents of each of which are incorporated herein by reference.

### FIELD OF THE INVENTION

The present invention relates to a bridge circuit and a magnetic sensor including the bridge circuit. More particularly, the present invention relates to a bridge circuit formed of four MR elements and a magnetic sensor including the bridge circuit.

### BACKGROUND OF THE INVENTION

Magnetic sensors using magneto-resistance effect elements (MR elements) utilizing magneto-resistance effect (MR effect) are known. FIG. 5 is an equivalent circuit diagram of such a magnetic sensor. Specifically, the magnetic sensor includes a bridge circuit formed of four MR elements R1 to R4, a comparator that receives the potential between a node between the MR element R1 and the MR element R2 and a node between the MR element R3 and the MR element R4 to output the voltage corresponding to the potential difference, and a feedback resistor that feeds back the output from the comparator to one input. Such circuit elements are formed in the same chip to compose the magnetic sensor.

FIG. 6 is a plan view illustrating a pattern of the MR elements R1 to R4 in such a bridge circuit. Specifically, a serial connection body of the MR element R1 and the MR element R2 and a serial connection body of the MR element R3 and the MR element R4 are connected in parallel between power supply voltage Vcc and grounding GND. In each of the MR element R1 and the MR element R4 in the bridge circuit, multiple strips along a direction orthogonal to a magnetic-field detection direction are arranged in parallel at certain intervals and are sequentially connected so as to be folded back to form a zigzag pattern in which the multiple strips are electrically connected in series to each other. In each of the MR element R2 and the MR element R3 in the bridge circuit, multiple strips along the magnetic-field detection direction are arranged in parallel at certain intervals and are sequentially connected so as to be folded back to form a zigzag pattern in which the multiple strips are electrically connected in series to each other. Such a bridge circuit using the MR elements arranged in the zigzag patterns is proposed in Patent Document 1.

In detection of the position of a rotation operation, there are cases in which an operation angle range of the magnetic sensor is desirably increased as much as possible depending on applications. For example, liquid crystal screen portions of video cameras have rotation mechanisms and the orientations of images on the liquid crystal portions are inverted at angles that are set. At small detection angles, only slight rotation operations may invert the images on the liquid crystal portions. In order to increase the detection angle a little bit, it is necessary to increase magnets in size or devise the arrangement of the magnetic sensors. The degree of freedom of design is reduced with the decrease in size of terminals in recent years and it is desirable to provide the magnetic sensors having large detection angle ranges.

Patent Document 1: Japanese Unexamined Patent Application Publication No. 2007-225421

However, the magnetic sensors in the background art described above have the following problems.

Connecting the four MR elements R1 to R4 differing in at least one resistor body at the four nodes in a bridge pattern and applying power to opposing nodes cause offset voltage at the remaining opposing nodes. Specifically, connecting the serial connection body of the MR element R1 and the MR element R2 and the serial connection body of the MR element R3 and the MR element R4 in parallel between the power supply voltage Vcc and the grounding GND, as illustrated in FIG. 6, causes the offset voltage between a node a between the MR element R1 and the MR element R2 and a node b between the MR element R3 and the MR element R4. Upon application of the magnetic field, the MR elements output voltage. The detection level of a waveform shaping processor is set so as to be higher than the level based on the offset voltage from the MR elements. When the level based on the offset voltage from the MR elements exceeds the above detection level, the waveform shaping processor outputs a signal.

Upon application of magnetic field of ∠θ to the pattern illustrated in FIG. 6, relationship R=R0−ΔR×sin² θ is established between an angle θ between the current flowing through the MR elements and the magnetic field and the resistance value of the MR elements. In this equation, R0: the resistance value of the MR elements under no magnetic field and ΔR: the amount of change of resistance upon application of the magnetic field.

The offset voltage between the nodes a and b when voltage V is applied is represented by (Formula 1):

$$Vab = V \times \frac{( R 2 - \text{?} R 2 \times {cos }^{2} θ )}{( R 1 - Δ R 1 \times {sin}^{2} θ ) + ( R 2 - Δ R 2 \times {cos}^{2} θ )} - V \times \frac{( R 4 - Δ R 4 \times {sin}^{2} θ )}{( R 3 \text{?} Δ R 3 \times {cos}^{2} θ ) \text{?} ( R 4 - Δ R 4 \times {sin}^{2} θ )} \\ \text{?} \text{indicates text missing or illegible when filed} \qquad ( Formula 1 )$$

The relationship between the magnetic field of ∠θ and mid-point potential is represented by a curve c illustrated in FIG. 7. The angle of the magnetic field exceeding the offset voltage value under no magnetic field is limited to a range from 45° to 135°. In other words, no signal is output from the waveform shaping processor outside this angel range and nothing is detected.

### SUMMARY OF THE INVENTION

Accordingly, it is an object of the present invention to provide a magnetic sensor having a large magnetic-field detection angle range and a bridge circuit used in the magnetic sensor.

In order to achieve the above object, a magnetic sensor according to the present invention includes a bridge circuit in which a serial connection body of a first MR element and a second MR element and a serial connection body of a third MR element and a fourth MR element are connected in parallel between power supplies, and a comparator that receives potential between a node between the first MR element and the second MR element and a node between the third MR element and the fourth MR element to have an output corresponding to a potential difference between both the nodes. In each of the first and fourth MR elements in the bridge circuit, multiple strips along a direction substantially orthogonal to a magnetic-field detection direction are arranged in parallel at certain intervals and are sequentially connected so as to be folded back to form a zigzag pattern in which the multiple strips are electrically connected in series to each other. In each of the second and third MR elements in the bridge circuit, multiple strips, on the whole, along the direction substantially orthogonal to the magnetic-field detection direction are arranged in parallel at certain intervals and are sequentially connected so as to be folded back and, in each of the multiple strips, multiple strips along the magnetic-field detection direction are arranged in parallel at certain intervals and are sequentially connected so as to be folded back to form a zigzag pattern in which the multiple strips are electrically connected in series to each other.

A bridge circuit according to the present invention is provided in which a serial connection body of a first MR element and a second MR element and a serial connection body of a third MR element and a fourth MR element are connected in parallel between power supplies. In each of the first and fourth MR elements, multiple strips along a direction substantially orthogonal to a magnetic-field detection direction are arranged in parallel at certain intervals and are sequentially connected so as to be folded back to form a zigzag pattern in which the multiple strips are electrically connected in series to each other. In each of the second and third MR elements, multiple strips, on the whole, along the direction substantially orthogonal to the magnetic-field detection direction are arranged in parallel at certain intervals and are sequentially connected so as to be folded back and, in each of the multiple strips, multiple strips along the magnetic-field detection direction are arranged in parallel at certain intervals and are sequentially connected so as to be folded back to form a zigzag pattern in which the multiple strips are electrically connected in series to each other.

According to the present invention, it is possible to increase the magnetic-field detection angle range.

### BRIEF DESCRIPTION OF DRAWINGS

FIG. 1A is a plan view for describing a bridge circuit in a magnetic sensor according to a first embodiment of the present invention.

FIG. 1B is a partially enlarged view for describing the shape of the bridge circuit in the magnetic sensor according to the first embodiment of the present invention in detail.

FIG. 2 is a graph illustrating the relationship between the line length of an MR element and the rate of change of resistance.

FIG. 3 is a plan view for describing a bridge circuit in a magnetic sensor according to a second embodiment of the present invention.

FIG. 4A is a plan view for describing a bridge circuit in a magnetic sensor according to another embodiment of the present invention.

FIG. 4B is a plan view for describing a bridge circuit in a magnetic sensor according to another embodiment of the present invention.

FIG. 5 is an equivalent circuit diagram of a conventional magnetic sensor.

FIG. 6 is a plan view illustrating an exemplary MR pattern in a bridge circuit in a conventional magnetic sensor.

FIG. 7 is a graph illustrating the relationship between magnetic field of ∠θ and mid-point potential in a conventional magnetic sensor.

### DETAILED DESCRIPTION OF THE PREFERRED EMBODIMENTS

Before detailed description of preferred embodiments of the present invention, the offset voltage of the magnetic sensor will now be described again. If the MR elements R2 and R3 illustrated in FIG. 6 are replaced with resistor bodies that are not affected by the magnetic field, the offset voltage between the nodes a and b is represented by (Formula 2):

$$Vab = V \times \frac{R 2}{( R 1 - Δ R 1 \times {sin}^{2} θ ) + R 2} - V \times \frac{( R 4 - Δ R 4 \times {sin}^{2} θ )}{R 3 + ( R 4 - Δ R 4 \times {sin}^{2} θ )} \qquad ( Formula 2 )$$

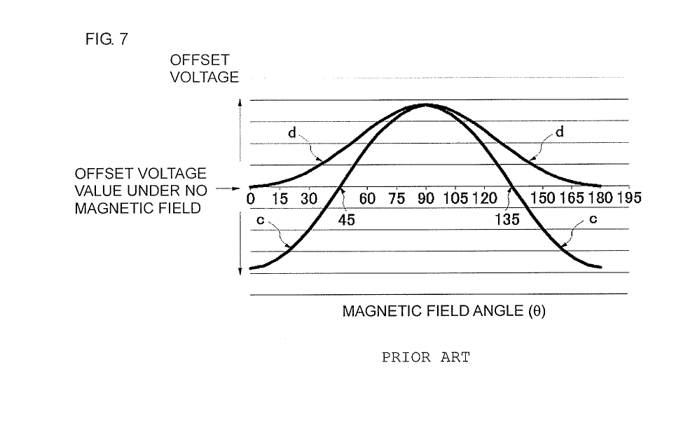

In this case, the relationship between the magnetic field of ∠θ and the mid-point potential is represented by a curve d illustrated in FIG. 7. The angle of the magnetic field exceeding the offset voltage value under no magnetic field is greatly increased, compared with the case in (Formula 1).

As described above, replacing the MR elements R2 and R3 in the bridge circuit with the resistor bodies that do not depend on the magnetic field allows the detection angle of the magnetic sensor to be increased. Accordingly, the MR elements R2 and R3 may be replaced with common semiconductor resistors. However, in consideration of practical mass production, the resistance values of the resistors made of semiconductor are varied from about ±10% to about 20%. Consequently, the relative precision with the MR elements is degraded and the balance of the mid-point potential is not capable of being controlled. Thus, the replacement of the MR elements R2 and R3 with the common semiconductor resistors is not practical.

Accordingly, in the present invention, the R2 and R3 in the bridge circuit, which are formed of the MR elements, are formed into a shape that is less affected by the magnetic field to increase the detection angle range.

### First Embodiment

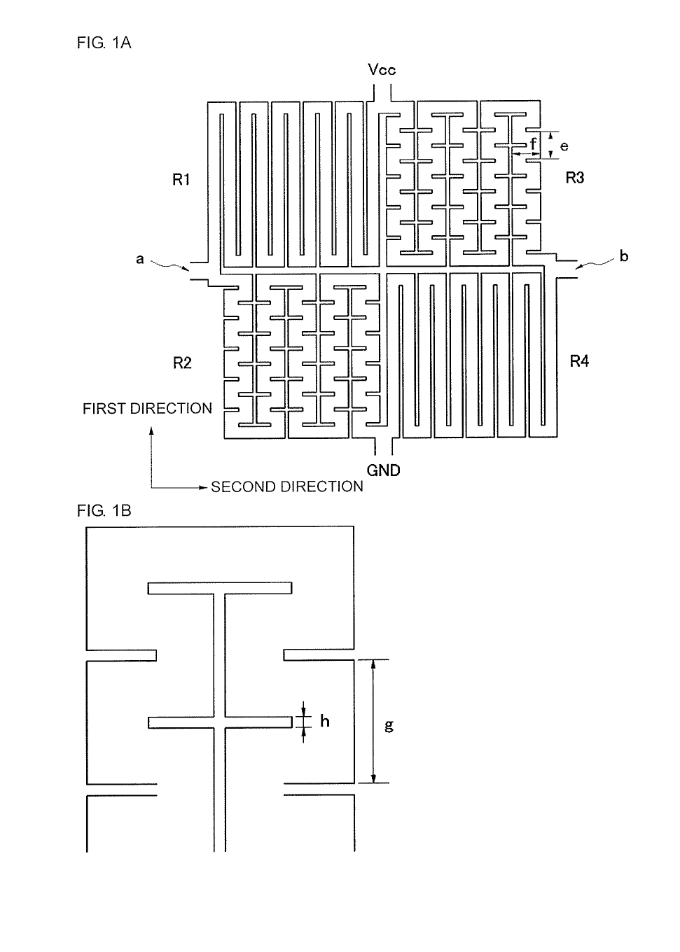

First, a bridge circuit according to a first embodiment of the present invention and a magnetic sensor including the bridge circuit will now be described with reference to the drawings. FIG. 1A is a plan view for describing the bridge circuit in the magnetic sensor according to the first embodiment of the present invention. FIG. 1B is a partially enlarged view for describing the shape of the bridge circuit in detail.

The magnetic sensor according to the present embodiment includes a bridge circuit in which a serial connection body of an MR element R1 and an MR element R2 and a serial connection body of an MR element R3 and an MR element R4 are connected in parallel between power supply voltage Vcc and grounding GND, a comparator (not illustrated) which receives the potential between a node a between the MR element R1 and the MR element R2 and a node b between the MR element R3 and the MR element R4 to have an output corresponding to the potential difference between both the nodes, and a feedback resistor (not illustrated) which feeds back the output from the comparator to one input, as illustrated in FIG. 1A. Such circuit elements are formed in the same chip to compose the magnetic sensor.

In addition, the magnetic sensor is featured in the pattern of the MR elements R1 to R4 composing the bridge circuit. Specifically, as illustrated in FIG. 1A, in each of the MR element R1 and the MR element R4 in the bridge circuit, multiple strips along a direction substantially orthogonal to a magnetic-field detection direction are arranged in parallel at certain intervals and are sequentially connected so as to be folded back to form a zigzag pattern in which the multiple strips are electrically connected in series to each other. In addition, as illustrated in FIG. 1A, in each of the MR element R2 and the MR element R3 in the bridge circuit, multiple strips, on the whole, along the direction substantially orthogonal to the magnetic-field detection direction are arranged in parallel at certain intervals and are sequentially connected so as to be folded back and, in each of the multiple strips, multiple strips along the magnetic-field detection direction are arranged in parallel at certain intervals and are sequentially connected so as to be folded back to form a zigzag pattern in which the multiple strips are electrically connected in series to each other. The portions that are folded back to be connected are formed into a substantially linear U shape.

More specifically, as illustrated in FIG. 1A, the MR elements R2 and R3 are composed of the shortest possible straight lines, and straight lines of the same length, like an element e and an element f in FIG. 1A, are arranged so as to be orthogonal to each other to compose the MR elements R2 and R3. In other words, as for the MR element R2, the length of the straight lines in a first direction in FIG. 1A is made equal to the length of the straight lines in a second direction orthogonal to the first direction. Also as for the MR element R3, the length of the straight lines in the first direction is made equal to the length of the straight lines in the second direction.

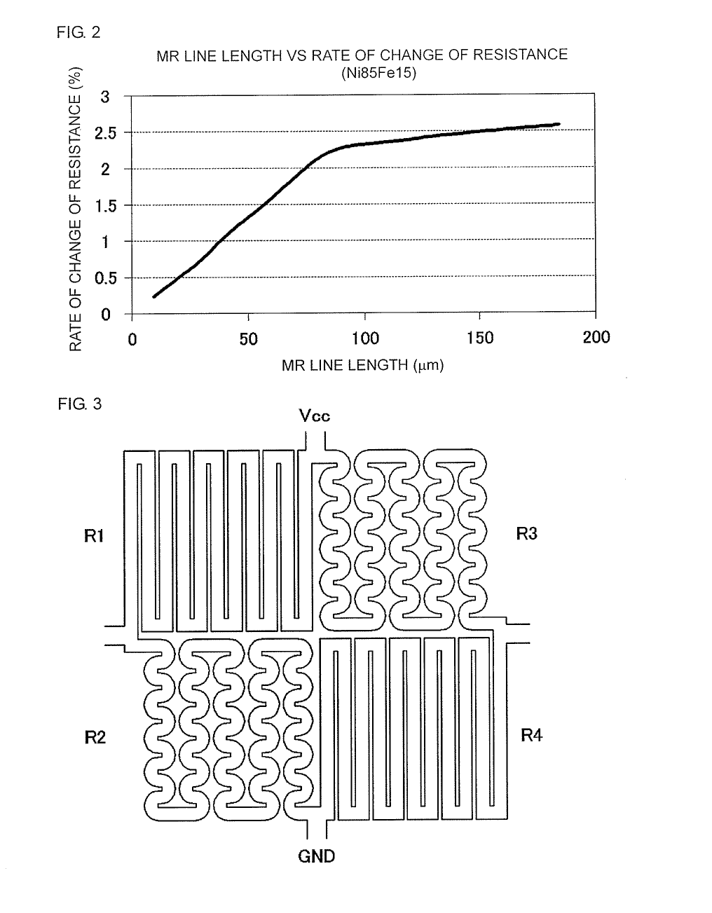

Since each of the MR elements R2 and R3 is composed of the short lines, the resistance change of the MR elements, which are anisotropic magneto-resistance elements, relative to the magnetic field is greatly smaller than that of the MR elements R1 and R4. FIG. 2 illustrates the relationship between the line length of the MR element and the rate of change of resistance. A case in which the MR element is made of Ni_{0.85}Fe_{0.15} is illustrated in FIG. 2. For example, when a length h resulting from exclusion of an area overlapped with the orthogonal pattern from a line g in FIG. 1B is shorter than or equal to 10 μm, the change of resistance of the MR element is reduced to ⅕ or less, compared with lines of 80 μm or longer, as illustrated in FIG. 2.

Arranging the MR elements having the same shape so as to be orthogonal to each other as the R2 and R3 produces a resistance value R represented by (Formula 3) when the magnetic field of ∠θ is applied:

R=(R0−ΔR×sin² θ)+(R0−ΔR×cos² θ)

R=2R0−ΔR(sin² θ+cos² θ)

R=2R0−ΔR (Formula 3)

Accordingly, the resistance value R does not theoretically depend on the angle of the applied magnetic field.

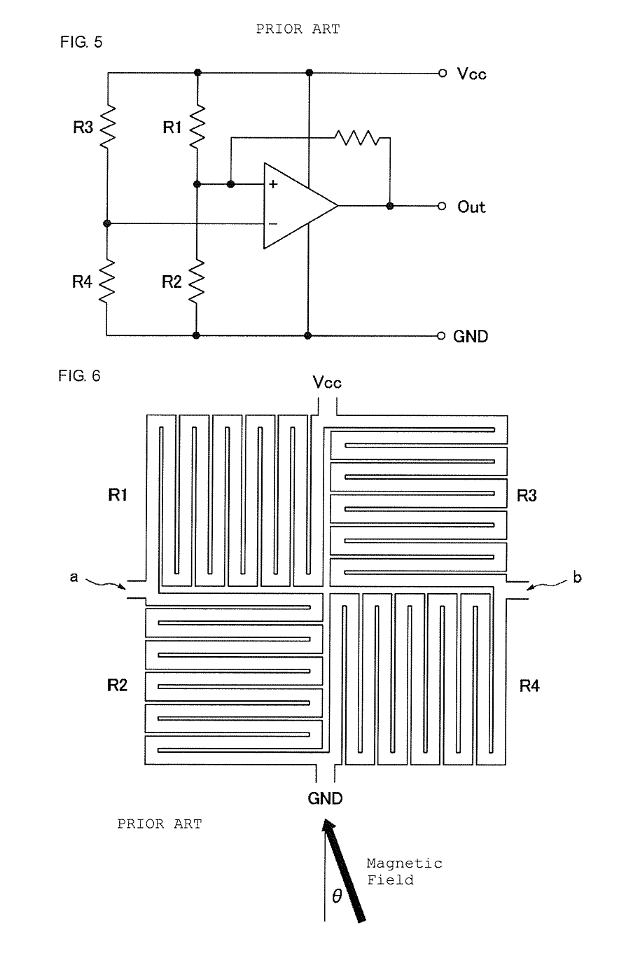

As described above, when the bridge circuit in FIG. 5 composed of the MR elements in FIG. 1A is considered, the MR elements R2 and R3 have significantly small resistance change due to the magnetic field and do not depend on the direction of the magnetic field. Consequently, the offset voltage is equal to (Formula 2). The relationship between the magnetic field of ∠θ and the mid-point potential is represented by the curve d illustrated in FIG. 7. Accordingly, the MR sensor having a large rotation detection angle is provided.

According to the magnetic sensor of the present embodiment, the magnetic-field detection angle range is increased. For example, when magnetic field of θ=45° is applied, the magnetic sensor composed of the MR elements in FIG. 6 does not operate because all the resistances of the MR elements R1 to R4 are varied in the same manner. In contrast, the magnetic sensor composed of the MR elements in FIG. 1A is capable of operating.

### Second Embodiment

Next, a bridge circuit according to a second embodiment of the present invention and a magnetic sensor including the bridge circuit will now be described with reference to the drawing. FIG. 3 is a plan view for describing the bridge circuit in the magnetic sensor according to the second embodiment of the present invention. A detailed description of the content common to the first embodiment is omitted herein.

The magnetic sensor of the present embodiment differs from the first embodiment in the pattern shape of the MR elements R1 to R4 composing the bridge circuit. Specifically, as illustrated in FIG. 3, in each of the MR element R1 and the MR element R4 in the bridge circuit, multiple strips along a direction substantially orthogonal to the magnetic-field detection direction are arranged in parallel at certain intervals and are sequentially connected so as to be folded back to form a zigzag pattern in which the multiple strips are electrically connected in series to each other. In addition, as illustrated in FIG. 3, in each of the MR element R2 and the MR element R3 in the bridge circuit, multiple strips, on the whole, along the direction substantially orthogonal to the magnetic-field detection direction are arranged in parallel at certain intervals and are sequentially connected so as to be folded back and, in each of the multiple strips, multiple strips along the magnetic-field detection direction are arranged in parallel at certain intervals and are sequentially connected so as to be folded back to form a zigzag pattern in which the multiple strips are electrically connected in series to each other.

As illustrated in FIG. 3, in the present embodiment, in the MR elements R2 and the MR element R3 in the bridge circuit, the multiple strips are sequentially connected so as to be folded back in a pattern including multiple 180-degree R shapes to form the zigzag pattern in which the multiple strips are electrically connected in series to each other. In other words, the portions that are folded back to be connected are formed into a substantially non-linear U shape.

Also when the MR element R2 and the MR element R3 having the shape and the pattern in the present embodiment are used, the MR element R2 and the MR element R3 do not depend on the direction of the magnetic field and the magnetic-field detection angle range is increased, as in the magnetic sensor of the first embodiment.

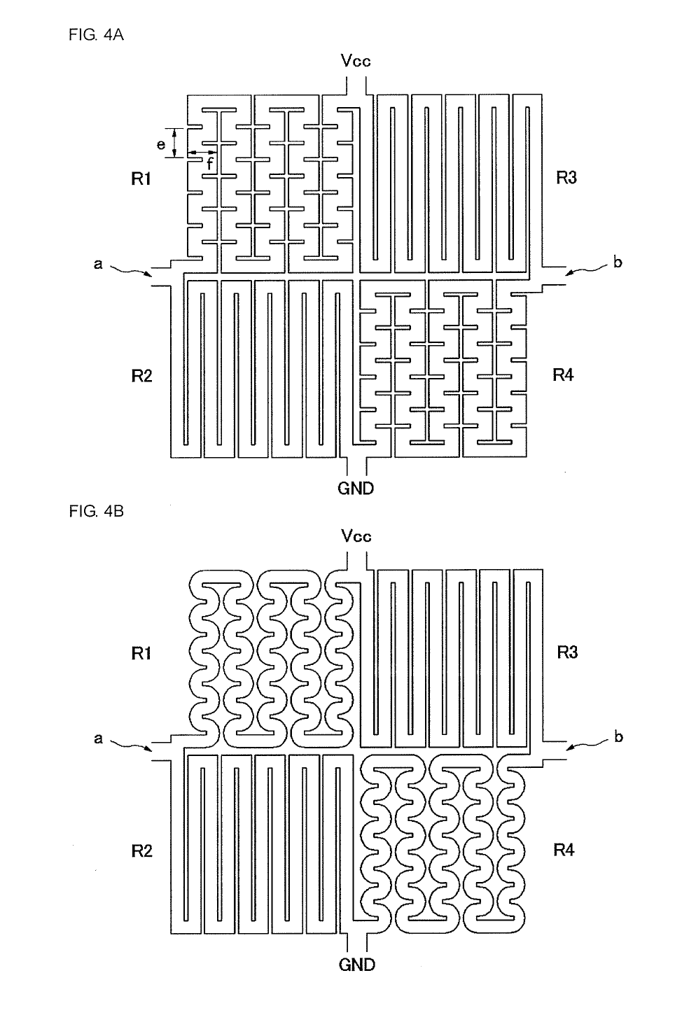

Although the preferred embodiments of the present invention are described above, the present invention is not limited to the above embodiments. The arrangement of the pattern of the MR elements in the bridge circuit is not limited to the first embodiment illustrated in FIG. 1A and FIG. 1B and to the second embodiment illustrated in FIG. 3. For example, patterns of the MR elements in the bridge circuit illustrated in FIG. 4A and FIG. 4B may be adopted.

FIG. 4A is a modification of FIG. 1A and FIG. 1B. In each of the MR elements R1 and R4, multiple strips, on the whole, along the direction substantially orthogonal to the magnetic-field detection direction are arranged in parallel at certain intervals and are sequentially connected so as to be folded back and, in each of the multiple strips, multiple strips along the magnetic-field detection direction are arranged in parallel at certain intervals and are sequentially connected so as to be folded back to form a zigzag pattern in which the multiple strips are electrically connected in series to each other.

FIG. 4B is a modification of FIG. 3. In each of the MR elements R1 and R4, multiple strips, on the whole, along the direction substantially orthogonal to the magnetic-field detection direction are arranged in parallel at certain intervals and are sequentially connected so as to be folded back and, in each of the multiple strips, multiple strips along the magnetic-field detection direction are arranged in parallel at certain intervals and are sequentially connected so as to be folded back to form a zigzag pattern in which the multiple strips are electrically connected in series to each other. As in the case in FIG. 3, the multiple strips are sequentially connected so as to be folded back in the pattern including the multiple 180-degree R shapes to form the zigzag pattern in which the multiple strips are electrically connected in series to each other.

In these cases, the MR elements R1 and R4 have significantly small resistance change due to the magnetic field and do not depend on the direction of the magnetic field. Accordingly, the MR sensor having a large rotation detection angle is provided.

Although the comparator and the feedback resistor are formed in the same chip as that of the bridge circuit in the first embodiment, the comparator and the feedback resistor may be formed in a different chip.

Although the invention of the present application is described above with reference to the preferred embodiments, the invention of the present application is not limited to the above embodiments. Various changes and modified embodiments of the configuration and the detailed portions of the invention of the present application will be obvious to those skilled in the art without departing from the scope of the invention of the present application.

### INDUSTRIAL APPLICABILITY

Electronic devices and industrial equipment requiring the position detection are considered as exemplary applications of the present invention.

### REFERENCE SIGNS LIST

R1, R2, R3, R4 MR element

a, b node

g line

1. A magnetic sensor comprising:
a first MR element having a plurality of first strips extending parallel to each other in a first direction to form a zigzag pattern and being electrically connected in series to each other;
a second MR element serially connected to the first MR element and having a plurality of second strips extending parallel to each other in the first direction to form a zigzag pattern and being electrically connected in series to each other, where each of the plurality of second strips includes multiple strips extending parallel to each other in a second direction substantially orthogonal to the first direction to form a zigzag pattern and being electrically connected in series to each other;
a third MR element having a plurality of third strips extending parallel to each other in the first direction to form a zigzag pattern and being electrically connected in series to each other, where each of the plurality of third strips includes multiple strips extending parallel to each other in the second direction substantially orthogonal to the first direction to form a zigzag pattern and being electrically connected in series to each other;
a fourth MR element serially connected to the third MR element and having a plurality of fourth strips extending parallel to each other in the first direction to form a zigzag pattern and being electrically connected in series to each other; and
a comparator having a first input coupled to a first node between the first MR element and the second MR element and a second input coupled to second node between the third MR element and the fourth MR element,
wherein the first and second MR elements are connected in parallel to the third and fourth MR elements.

2. The magnetic sensor according to claim 1, wherein the first and second MR elements and the third and fourth MR elements are connected between power supplies.

3. The magnetic sensor according to claim 1, wherein the comparator outputs a potential difference between the first node and the second node.

4. The magnetic sensor according to claim 1, wherein each of the multiple strips in the second and third MR elements have a length shorter than each of the plurality of first and fourth strips of the first and fourth MR elements, respectively.

5. The magnetic sensor according to claim 1, wherein each of the multiple strips of the second and third MR elements comprises a straight line and a straight-line distance resulting from exclusion of an area where respective straight lines intersect with each other is shorter than or equal to 10 μm.

6. The magnetic sensor according to claim 1, wherein each of the multiple strips in each of the second and third MR elements are sequentially connected so as to be folded back in a pattern including multiple 180-degree R shapes.

7. The magnetic sensor according to claim 1, wherein each of the multiple strips in each of the first and fourth MR elements are folded back and connected to form a plurality of substantially linear U shapes.

8. The magnetic sensor according to claim 1, wherein each of the multiple strips in each of the second and third MR elements are folded back and connected to form a plurality of substantially non-linear U shapes.

9. The magnetic sensor according to claim 1, wherein each of the first, second, third and fourth MR elements comprises Ni_{0.85}Fe_{0.15}.

10. A bridge circuit sensor comprising:
a first MR element having a plurality of first strips extending parallel to each other in a first direction to form a zigzag pattern and being electrically connected in series to each other;
a second MR element serially connected to the first MR element and having a plurality of second strips extending parallel to each other in the first direction to form a zigzag pattern and being electrically connected in series to each other, where each of the plurality of second strips includes multiple strips extending parallel to each other in a second direction substantially orthogonal to the first direction to form a zigzag pattern and being electrically connected in series to each other;
a third MR element having a plurality of third strips extending parallel to each other in the first direction to form a zigzag pattern and being electrically connected in series to each other, where each of the plurality of third strips includes multiple strips extending parallel to each other in the second direction substantially orthogonal to the first direction to form a zigzag pattern and being electrically connected in series to each other; and
a fourth MR element serially connected to the third MR element and having a plurality of fourth strips extending parallel to each other in the first direction to form a zigzag pattern and being electrically connected in series to each other,
wherein the first and second MR elements are connected in parallel to the third and fourth MR elements.

11. The bridge circuit sensor according to claim 10, wherein the first and second MR elements and the third and fourth MR elements are connected between power supplies.

12. The bridge circuit according to claim 10, wherein each of the multiple strips in the second and third MR elements have a length shorter than each of the plurality of first and fourth strips of the first and fourth MR elements, respectively.

13. The bridge circuit according to claim 10, wherein each of the multiple strips of the second and third MR elements comprises a straight line and a straight-line distance resulting from exclusion of an area where respective straight lines intersect with each other is shorter than or equal to 10 μm.

14. The bridge circuit according to claim 10, wherein each of the multiple strips in each of the second and third MR elements are sequentially connected so as to be folded back in a pattern including multiple 180-degree R shapes.

15. The bridge circuit according to claim 10, wherein each of the multiple strips in each of the first and fourth MR elements are folded back and connected to form a plurality of substantially linear U shapes.

16. The bridge circuit according to claim 10, wherein each of the multiple strips in each of the second and third MR elements are folded back and connected to form a plurality of substantially non-linear U shapes.

17. The bridge circuit according to claim 10, wherein each of the first, second, third and fourth MR elements comprises Ni_{0.85}Fe_{0.15}.
